(19) United States
(12) Patent Application Publication
(10) Pub. No.: US 2023/0179928 A1
(43) Pub. Date: Jun. 8, 2023

(54) MEMS MICROPHONE AND METHOD OF MANUFACTURING THE SAME

(71) Applicant: DB HITEK CO., LTD., Seoul (KR)

(72) Inventor: Min Hyun JUNG, Chungcheongbuk-do (KR)

(21) Appl. No.: 18/073,020

(22) Filed: Dec. 1, 2022

(30) Foreign Application Priority Data
Dec. 3, 2021 (KR) 10-2021-0171528

(51) Int. Cl. H04R 19/04; B81B 3/00; B81C 1/00; H04R 31/00

(52) U.S. Cl. CPC H04R 19/04; B81B 3/007; B81C 1/00658; H04R 31/00; B81B 2201/0257; B81B 2203/0127; B81B 2203/0307; B81B 2203/04; H04R 2201/003

(57) ABSTRACT

A MEMS microphone includes a substrate having a cavity, a diaphragm comprising a first electrode layer disposed above the cavity, and a back plate comprising a second electrode layer disposed above the first electrode layer and a support layer disposed on the second electrode layer. The second electrode layer includes a conductive layer pattern, and a reinforcing pattern configured to surround the conductive layer pattern and to increase structural rigidity of the support layer.

### CROSS-REFERENCE TO RELATED APPLICATION

This application claims the priority benefit of Korean Patent Application No. 10-2021-0171528, filed on Dec. 3, 2021, and all the benefits accruing therefrom under 35 U.S.C. § 119, the contents of which are incorporated by reference in their entirety.

### TECHNICAL FIELD

The present disclosure relates to a MEMS (Micro Electro Mechanical System) microphone and a method of manufacturing the same. More specifically, the present disclosure relates to a MEMS microphone capable of converting a sound into an acoustic signal using a diaphragm configured to be vibrated by a sound pressure and a method of manufacturing the same.

### BACKGROUND

A MEMS microphone may be used to convert a sound into an acoustic signal and may be manufactured by a MEMS technology. For example, the MEMS microphone may include a diaphragm disposed above a substrate and a back plate disposed above the diaphragm. The diaphragm and the back plate may be supported by a plurality of anchors on the substrate, and a predetermined air gap may be provided between the diaphragm and the back plate.

The diaphragm may include a first conductive layer used as a first electrode, and the back plate may include a second conductive layer used as a second electrode, and a support layer formed on the second conductive layer to support the second conductive layer. The diaphragm may be vibrated by an applied sound pressure, whereby the air gap between the diaphragm and the back plate may be changed. Further, a capacitance between the diaphragm and the back plate may be changed by the change in the air gap, and the acoustic signal may be detected from the change in the capacitance.

Meanwhile, when the thickness of the support layer is relatively thin, the support layer may sag downward. In this case, the capacitance between the diaphragm and the back plate may change, and thus the sensitivity of the MEMS microphone may deteriorate.

### SUMMARY

The present disclosure provides a MEMS microphone capable of improving structural rigidity of a supporting layer and a method of manufacturing the same.

In accordance with an aspect of the present disclosure, a MEMS microphone may include a substrate having a cavity, a diaphragm comprising a first electrode layer disposed above the cavity, and a back plate comprising a second electrode layer disposed above the first electrode layer and a support layer disposed on the second electrode layer. Particularly, the second electrode layer may include a conductive layer pattern, and a reinforcing pattern configured to surround the conductive layer pattern and to increase structural rigidity of the support layer.

In accordance with some embodiments of the present disclosure, the reinforcing pattern may include a plurality of protrusions protruding outward from the conductive layer pattern.

In accordance with some embodiments of the present disclosure, the protrusions may be made of the same material as the conductive layer pattern. In such case, the second electrode layer may have the same size as the first electrode layer.

In accordance with some embodiments of the present disclosure, the protrusions may be made of a material different from that of the conductive layer pattern. In such case, the conductive layer pattern may have the same size as the first electrode layer.

In accordance with some embodiments of the present disclosure, the conductive layer pattern may be made of impurity-doped polysilicon, and the protrusions may be made of undoped polysilicon.

In accordance with some embodiments of the present disclosure, the reinforcing pattern may have a ring shape surrounding the conductive layer pattern and may include a plurality of protrusions protruding outward.

In accordance with some embodiments of the present disclosure, the conductive layer pattern may include a plurality of protrusions protruding outward, and the reinforcing pattern may have a ring shape surrounding the conductive layer pattern and may include a plurality of second protrusions protruding outward. In such case, the conductive layer pattern may have the same size as the first electrode layer.

In accordance with some embodiments of the present disclosure, the diaphragm may further include a first anchor portion disposed on the substrate to surround the cavity and supporting the first electrode layer.

In accordance with some embodiments of the present disclosure, the back plate may further include a second anchor portion disposed on the substrate to surround the first anchor portion and fixing the support layer on the substrate.

In accordance with another aspect of the present disclosure, a method of manufacturing a MEMS microphone may include forming a diaphragm comprising a first electrode layer above a substrate, forming a back plate comprising a second electrode layer disposed above the first electrode layer and a support layer disposed on the second electrode layer, and forming a cavity for exposing the diaphragm through the substrate. Particularly, the second electrode layer may include a conductive layer pattern, and a reinforcing pattern configured to surround the conductive layer pattern and to increase structural rigidity of the support layer.

In accordance with some embodiments of the present disclosure, the forming the diaphragm may include forming a first insulating layer on the substrate, forming a first silicon layer on the first insulating layer, and performing an ion implantation process to form a portion of the first silicon layer as the first electrode layer.

In accordance with some embodiments of the present disclosure, the forming the back plate may include forming a second insulating layer on the diaphragm, forming a second silicon layer on the second insulating layer, performing an ion implantation process to form the second silicon layer as a conductive layer, and patterning the conductive layer to acquire the conductive layer pattern and the reinforcing pattern. In such case, the reinforcing pattern may include a plurality of protrusions protruding outward from the conductive layer pattern. Further, the second electrode layer may have the same size as the first electrode layer.

In accordance with some embodiments of the present disclosure, the forming the back plate may include forming a second insulating layer on the diaphragm, forming a second silicon layer on the second insulating layer, performing an ion implantation process to form a portion of the second silicon layer as the conductive layer pattern, and patterning the second silicon layer to acquire the reinforcing pattern. In such case, the reinforcing pattern may include a plurality of protrusions protruding outward from the conductive layer pattern. Further, the conductive layer pattern may have the same size as the first electrode layer.

In accordance with some embodiments of the present disclosure, the reinforcing pattern may have a ring shape surrounding the conductive layer pattern and may include a plurality of protrusions protruding outward.

In accordance with some embodiments of the present disclosure, the conductive layer pattern may include a plurality of protrusions protruding outward, and the reinforcing pattern may have a ring shape surrounding the conductive layer pattern and may include a plurality of second protrusions protruding outward.

In accordance with some embodiments of the present disclosure, the forming the diaphragm may include forming a first insulating layer on the substrate, patterning the first insulating layer to form a first anchor channel having a circular ring shape surrounding the cavity and exposing a portion of the substrate, forming a first silicon layer on the first insulating layer and inner surfaces of the first anchor channel, performing the ion implantation process to form a portion of the first silicon layer formed on the first insulating layer inside the first anchor channel as the first electrode layer, and patterning the first silicon layer to acquire a first anchor portion for supporting the first electrode layer in the first anchor channel.

In accordance with some embodiments of the present disclosure, the forming the back plate may include forming a second insulating layer on the diaphragm and the first insulating layer, forming the conductive layer pattern and the reinforcing pattern on the second insulating layer, patterning the first insulating layer and the second insulating layer to form a second anchor channel having a circular ring shape surrounding the first anchor portion and exposing a portion of the substrate, and forming a support layer on the conductive layer pattern, the reinforcing pattern, the second insulating layer, and inner surfaces of the second anchor channel. In such case, a portion of the support layer formed on the inner surfaces of the second anchor channel may function as a second anchor portion for fixing the support layer on the substrate.

In accordance with the embodiments of the present disclosure as described above, the reinforcing pattern may increase the structural rigidity of the support layer, thereby preventing the support layer from sagging downward and preventing the MEMS microphone from deteriorating in sensitivity. In addition, the thickness of the support layer may be made relatively thin compared to the prior art, and thus the manufacturing cost of the MEMS microphone may be reduced.

The above summary of the present disclosure is not intended to describe each illustrated embodiment or every implementation of the present disclosure. The detailed description and claims that follow more particularly exemplify these embodiments.

### BRIEF DESCRIPTION OF THE DRAWINGS

Embodiments can be understood in more detail from the following description taken in conjunction with the accompanying drawings, in which:

FIG. 1 is a schematic plan view illustrating a MEMS microphone in accordance with an embodiment of the present disclosure;

FIG. 2 is a schematic cross-sectional view taken along a line I-I′ as shown in FIG. 1;

FIG. 3 is a schematic plan view illustrating a second electrode layer as shown in FIG. 2;

FIGS. 4 to 6 are schematic plan views illustrating other examples of the second electrode layer as shown in FIG. 3;

FIG. 7 is a flowchart illustrating a method of manufacturing the MEMS microphone as shown in FIGS. 1 and 2; and

FIGS. 8 to 20 are schematic cross-sectional views illustrating the method of manufacturing the MEMS microphone as shown in FIG. 7.

While various embodiments are amenable to various modifications and alternative forms, specifics thereof have been shown by way of example in the drawings and will be described in detail. It should be understood, however, that the intention is not to limit the claimed inventions to the particular embodiments described. On the contrary, the intention is to cover all modifications, equivalents, and alternatives falling within the spirit and scope of the subject matter as defined by the claims.

### DETAILED DESCRIPTION

Hereinafter, embodiments of the present invention are described in more detail with reference to the accompanying drawings. However, the present invention is not limited to the embodiments described below and is implemented in various other forms. Embodiments below are not provided to fully complete the present invention but rather are provided to fully convey the range of the present invention to those skilled in the art.

In the specification, when one component is referred to as being on or connected to another component or layer, it can be directly on or connected to the other component or layer, or an intervening component or layer may also be present. Unlike this, it will be understood that when one component is referred to as directly being on or directly connected to another component or layer, it means that no intervening component is present. Also, though terms like a first, a second, and a third are used to describe various regions and layers in various embodiments of the present invention, the regions and the layers are not limited to these terms.

Terminologies used below are used to merely describe specific embodiments, but do not limit the present invention. Additionally, unless otherwise defined here, all the terms including technical or scientific terms, may have the same meaning that is generally understood by those skilled in the art.

Embodiments of the present invention are described with reference to schematic drawings of ideal embodiments. Accordingly, changes in manufacturing methods and/or allowable errors may be expected from the forms of the drawings. Accordingly, embodiments of the present invention are not described being limited to the specific forms or areas in the drawings, and include the deviations of the forms. The areas may be entirely schematic, and their forms may not describe or depict accurate forms or structures in any given area, and are not intended to limit the scope of the present invention.

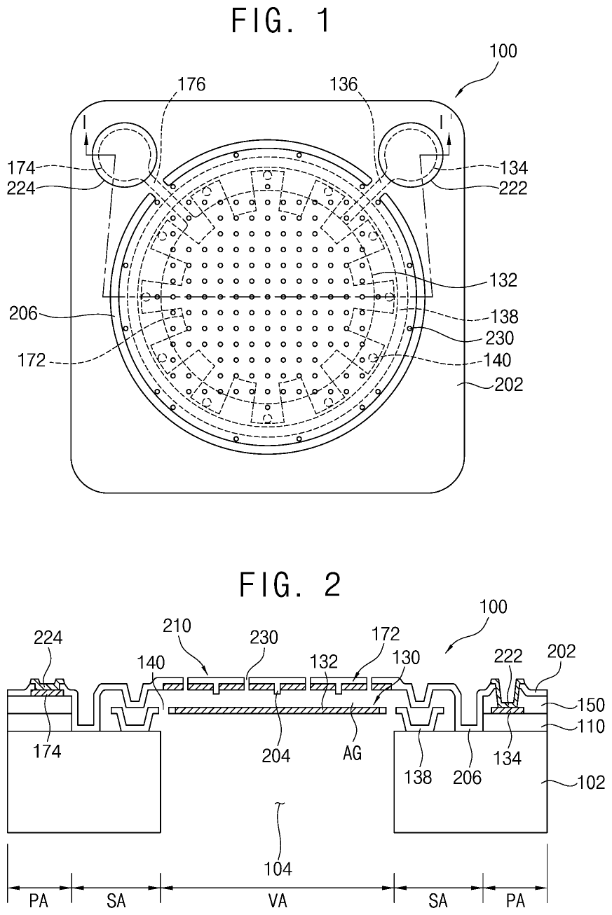

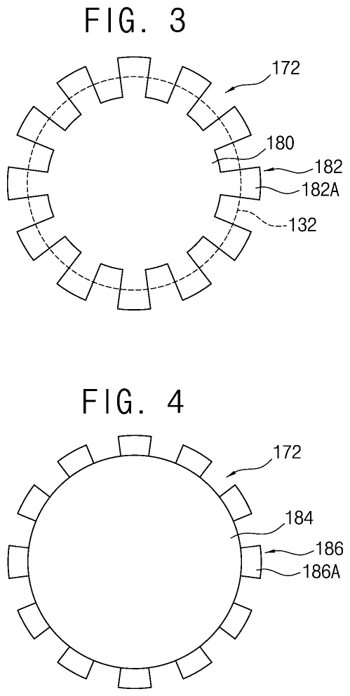

FIG. 1 is a schematic plan view illustrating a MEMS microphone in accordance with an embodiment of the present disclosure. FIG. 2 is a schematic cross-sectional view taken along a line I-I′ as shown in FIG. 1, and FIG. 3 is a schematic plan view illustrating a second electrode layer as shown in FIG. 2.

Referring to FIGS. 1 to 3, a MEMS microphone 100, in accordance with an embodiment of the present disclosure, may include a substrate 102 having a cavity 104, a diaphragm 130 disposed above the cavity 104, and a back plate 210 disposed above the diaphragm 130. For example, the diaphragm 130 may include a first electrode layer 132 disposed above the cavity 104, and the back plate 210 may include a second electrode layer 172 disposed above the first electrode layer 132 and a support layer 202 disposed on the second electrode layer 172. In particular, the second electrode layer 172 may include a conductive layer pattern 180 and a reinforcing pattern 182 configured to surround the conductive layer pattern 180 and to increase structural rigidity of the support layer 202.

For example, the substrate 102 may be a single-crystal silicon substrate, and may include a vibration area (VA), a support area (SA) surrounding the vibration area (VA), and a periphery area (PA) surrounding the support area (SA). In such case, the cavity 104 may be formed to pass through the vibration area (VA), and the diaphragm 130 may be exposed through the cavity 104.

The diaphragm 130 may be spaced apart from the substrate 102 to be vibrated by an applied sound pressure. For example, the first electrode layer 132 may be made of a conductive material and may have a disc shape. In addition, the diaphragm 130 may include a first anchor portion 138 configured to surround the first electrode layer 132 and to support the first electrode layer 132 on the substrate 102. For example, the first electrode layer 132 may be made of polysilicon doped with impurities, and the first anchor portion 138 may be made of undoped polysilicon. Further, the first anchor portion 138 may have a circular ring shape surrounding the first electrode layer 132 and may be formed on the support area (SA) of the substrate 102.

Further, the diaphragm 130 may include a first electrode pad 134 electrically connected to the first electrode layer 132. For example, the first electrode pad 134 may be connected to the first electrode layer 132 through a first connection pattern 136 as shown in FIG. 1. In this case, the first electrode pad 134 and the first connection pattern 136 may be made of the same material as the first electrode layer 132. Also, the diaphragm 130 may have a plurality of a plurality of ventilation holes 140. For example, the first anchor portion 138 may include an inner portion connected to the first electrode layer 132, and the ventilation holes 140 may be formed through the inner portion of the first anchor portion 138.

The support layer 202 may be made of an insulating material, for example, silicon nitride, and the second electrode layer 172 may be attached to a lower surface of the support layer 202. In particular, the back plate 210 may be disposed above the diaphragm 130 so that the second electrode layer 172 is spaced apart from the first electrode layer 132 by a predetermined distance. That is, a predetermined air gap (AG) may be provided between the first electrode layer 132 and the second electrode layer 172.

In addition, the back plate 210 may include a second anchor portion 206 for fixing the support layer 202 on the substrate 102, and a second electrode pad 174 electrically connected to the second electrode layer 172. As shown in FIG. 2, the second anchor portion 206 may be disposed on the support area (SA) of the substrate 102, and may have a circular ring shape surrounding the first anchor portion 138. As shown in FIG. 1, the second electrode layer 172 and the second electrode pad 174 may be electrically connected through a second connection pattern 176. For example, the second electrode pad 174 and the second connection pattern 176 may be formed of impurity-doped polysilicon, and the second anchor portion 206 may be made of silicon nitride.

A first insulating layer 110 may be disposed on an upper surface of the substrate 102, and a second insulating layer 150 may be disposed on the first insulating layer 110. In this case, the first electrode pad 134 may be disposed on the first insulating layer 110, and the second electrode pad 174 may be disposed on the second insulating layer 150. For example, the first insulating layer 110 and the second insulating layer 150 may be made of silicon oxide, and may be formed to surround the second anchor portion 206.

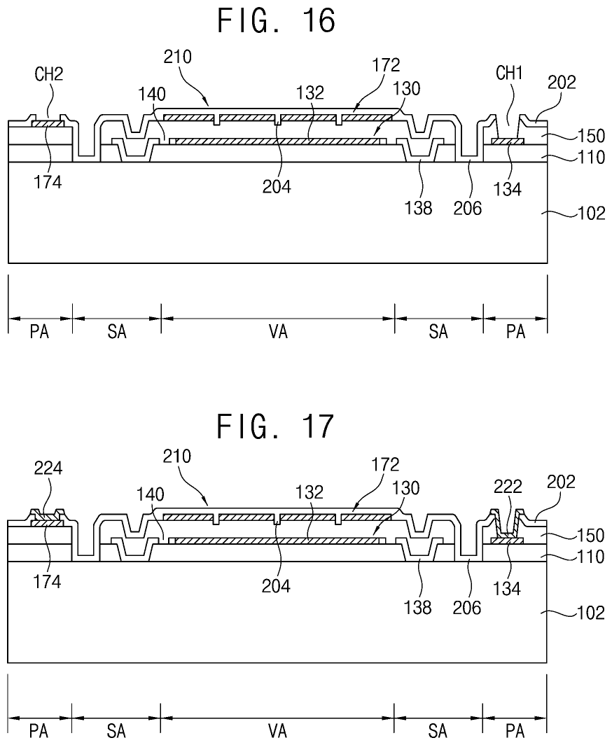

A first bonding pad 222 may be disposed on the first electrode pad 134, and a second bonding pad 224 may be disposed on the second electrode pad 174. For example, a first contact hole (CH1; refer to FIG. 16) exposing the first electrode pad 134 may be formed through the support layer 202 and the second insulating layer 150, and the first bonding pad 222 may be formed in the first contact hole (CH1). Further, a second contact hole (CH2; refer to FIG. 16) exposing the second electrode pad 174 may be formed through the support layer 202, and the second bonding pad 224 may be formed in the second contact hole (CH2).

In addition, the support layer 202 may include stoppers 204 penetrating through the second electrode layer 172 and protruding toward the first electrode layer 132. The stoppers 204 may be made of the same material as the support layer 202, and may be used to prevent the first electrode layer 132 and the second electrode layer 172 from contacting each other. Further, the back plate 210 may have a plurality of air holes 230 connected to the air gap (AG). The air holes 230 may be formed through the support layer 202 and the second electrode layer 172. For example, the air holes 230 may be disposed among the stoppers 204.

In accordance with an embodiment of the present disclosure, the reinforcing pattern 182 may include a plurality of protrusions 182A protruding outward from the conductive layer pattern 180. As shown in FIG. 3, as an example, the conductive layer pattern 180 may have a disk shape, and the protrusions 182A may be arranged at regular intervals along an edge of the conductive layer pattern 180. In particular, the protrusions 182A may be made of the same material as the conductive layer pattern 180, that is, impurity-doped polysilicon. In this case, the second electrode layer 172 may have the same size as the first electrode layer 132. In particular, the total area of the conductive layer pattern 180 and the protrusions 182A may be the same as the area of the first electrode layer 132, and the conductive layer pattern 180 and the protrusions 182A may have the same thickness as the first electrode layer 132.

FIGS. 4 to 6 are schematic plan views illustrating other examples of the second electrode layer as shown in FIG. 3.

Referring to FIG. 4, the second electrode layer 172 may include a disk-shaped conductive layer pattern 184 and a plurality of protrusions 186A protruding outward from the conductive layer pattern 184. In particular, the protrusions 186A may be made of a material different from that of the conductive layer pattern 184 and may be used as a reinforcing pattern 186 to increase structural rigidity of the support layer 202. For example, the conductive layer pattern 184 may be made of impurity-doped polysilicon, and the protrusions 186A may be made of undoped polysilicon. In this case, the conductive layer pattern 184 may have the same size as the first electrode layer 132. In particular, the conductive layer pattern 184 may have the same area and thickness as the first electrode layer 132.

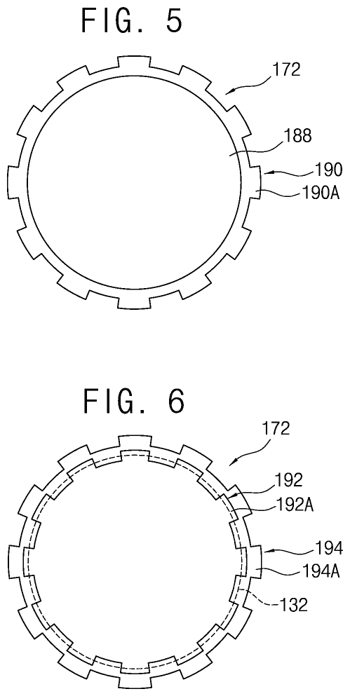

Referring to FIG. 5, the second electrode layer 172 may include a disk-shaped conductive layer pattern 188 and a circular ring-shaped reinforcing pattern 190 surrounding the conductive layer pattern 188. In particular, the reinforcing pattern 190 may include a plurality of protrusions 190A protruding outward, and may be made of a material different from that of the conductive layer pattern 188. For example, the conductive layer pattern 188 may be formed of impurity-doped polysilicon, and the reinforcing pattern 190 may be formed of undoped polysilicon. The conductive layer pattern 188 may have the same size as the first electrode layer 132. In particular, the conductive layer pattern 188 may have the same area and the same thickness as the first electrode layer 132. Meanwhile, as shown in FIG. 5, although the reinforcing pattern 190 is connected to the conductive layer pattern 188, alternatively, the reinforcing pattern 190 may be spaced apart from the conductive layer pattern 188 by a predetermined interval.

Referring to FIG. 6, the second electrode layer 172 may include a disk-shaped conductive layer pattern 192 and a circular ring-shaped reinforcing pattern 194 surrounding the conductive layer pattern 192. In particular, the conductive layer pattern 192 may include a plurality of protrusions 192A protruding outward, and the reinforcing pattern 194 may include a plurality of second protrusions 194A protruding outward. In this case, the reinforcing pattern 194 may be made of a material different from that of the conductive layer pattern 192. For example, the conductive layer pattern 192 may be formed of impurity-doped polysilicon, and the reinforcing pattern 194 may be formed of undoped polysilicon. In addition, the conductive layer pattern 192 may have the same size as the first electrode layer 132. In particular, the conductive layer pattern 192 may have the same area and the same thickness as the first electrode layer 132. Meanwhile, as shown in FIG. 6, although the reinforcing pattern 194 is connected to the conductive layer pattern 192, otherwise, the reinforcing pattern 194 may be spaced apart from the conductive layer pattern 192 by a predetermined interval.

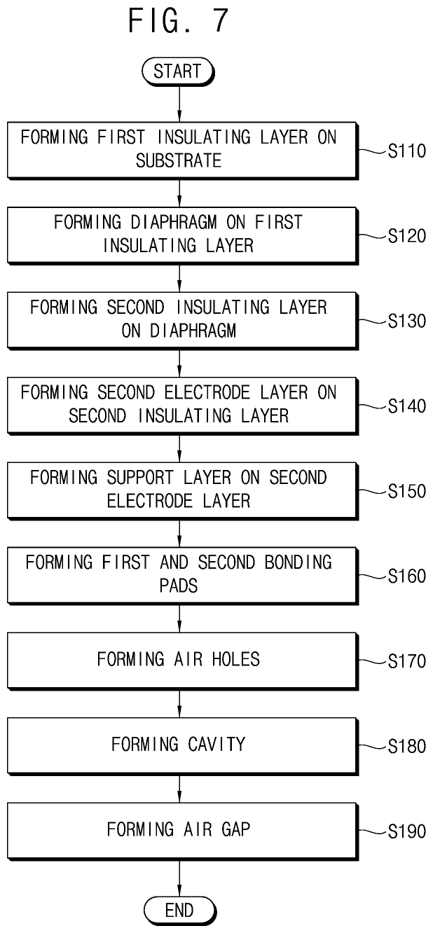

FIG. 7 is a flowchart illustrating a method of manufacturing the MEMS microphone as shown in FIGS. 1 and 2, and FIGS. 8 to 20 are schematic cross-sectional views illustrating the method of manufacturing the MEMS microphone as shown in FIG. 7.

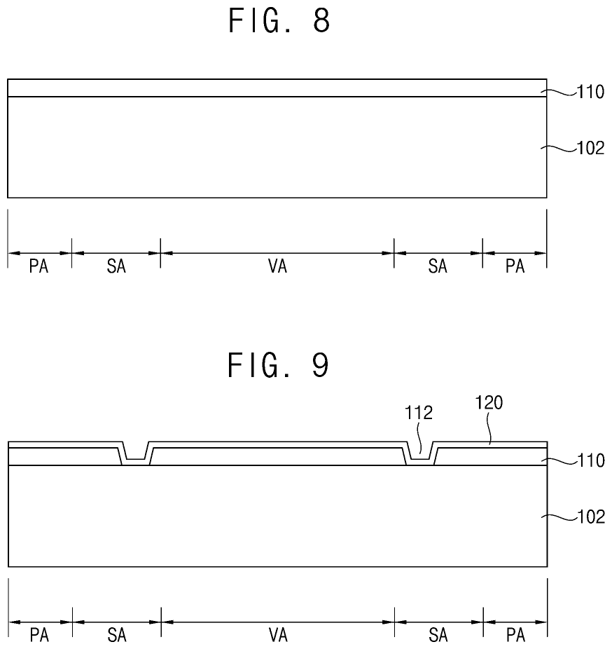

Referring to FIGS. 7 to 8, in step S110, a first insulating layer 110 may be formed on a substrate 102. For example, the substrate 102 may be a silicon wafer, and the first insulating layer 110 may be made of an insulating material such as silicon oxide. The first insulating layer 110 may be formed conformally, that is, to have an approximately uniform thickness through a chemical vapor deposition process.

Referring to FIG. 7, in step S120, a diaphragm 130 including a first electrode layer 132 may be formed on the first insulating layer 110.

Specifically, referring to FIG. 9, the first insulating layer 110 may be patterned to form a first anchor channel 112 exposing a surface portion of the substrate 102. The substrate 102 may include a vibration area (VA), a support area (SA) surrounding the vibration area (VA), and a periphery area (PA) surrounding the support area (SA), and the first anchor channel 112 may be formed on the support area (SA). In particular, the first anchor channel 112 may have a circular ring shape surrounding the vibration region (VA). For example, after forming a photoresist pattern exposing a portion where the first anchor channel 112 is to be formed on the first insulating layer 110, an etching process using the photoresist pattern as an etching mask may be performed, whereby the first anchor channel 112 may be formed to expose a portion of the upper surface of the substrate 102.

After forming the first anchor channel 112, a first silicon layer 120 may be conformally formed on the first insulating layer 110 to have an approximately uniform thickness. For example, the first silicon layer 120 may be a polysilicon layer formed by a chemical vapor deposition process. In such case, a portion of the first silicon layer 120 formed in the first anchor channel 112 may be used as a first anchor portion 138 for fixing a diaphragm 130 to be formed subsequently on the substrate 102.

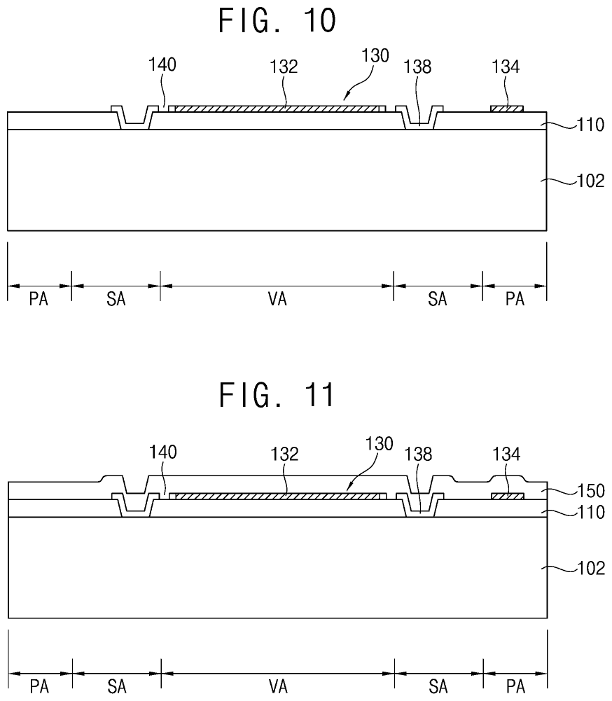

Referring to FIG. 10, an ion implantation process may be performed to form a portion of the first silicon layer 120 into a first electrode layer 132 having conductivity. Further, a first electrode pad 134 and a first connection pattern 136 (refer to FIG. 1) for connecting the first electrode layer 132 and the first electrode pad 134 may be formed in the first silicon layer 120 by the ion implantation process. For example, the first electrode layer 132 may have a disk shape and may be formed above the vibration region (VA). Further, the first electrode pad 134 may be formed above the periphery region (PA).

Then, the first silicon layer 120 may be patterned to form a diaphragm 130 including the first electrode layer 132, the first electrode pad 134, and the first connection pattern 136. In addition, a first anchor portion 138 for fixing the diaphragm 130 on the substrate 102 may be formed on the portion of the substrate 102 exposed by the first anchor channel 112, and a plurality of ventilation holes 140 may be formed between the first electrode layer 132 and the first anchor portion 138. For example, a photoresist pattern covering portions where the first electrode layer 132, the first anchor portion 138, the first electrode pad 134, and the first connection pattern 136 are to be formed may be formed on the first silicon layer 120, and then, an etching process using the photoresist pattern as an etching mask may be performed until the first insulating layer 110 is exposed.

Referring to FIGS. 7 and 11, in step S130, a second insulating layer 150 may be formed on the first insulating layer 110 and the diaphragm 130. For example, the second insulating layer 150 may include silicon oxide, and may be formed conformally, that is, to have an approximately uniform thickness by a chemical vapor deposition process.

Referring to FIG. 7, in step S140, a second electrode layer 172 may be formed on the second insulating layer 150.

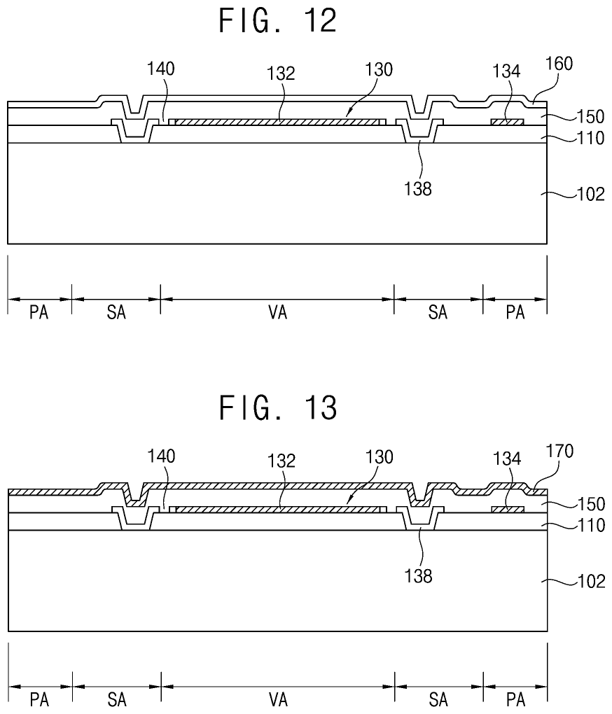

Specifically, referring to FIGS. 12 and 13, a second silicon layer 160 may be conformally formed on the second insulating layer 150 to have an approximately uniform thickness. For example, the second silicon layer 160 may be a polysilicon layer formed by a chemical vapor deposition process. Subsequently, an ion implantation process may be performed to form the second silicon layer 160 into a conductive layer 170, that is, a polysilicon layer doped with impurities.

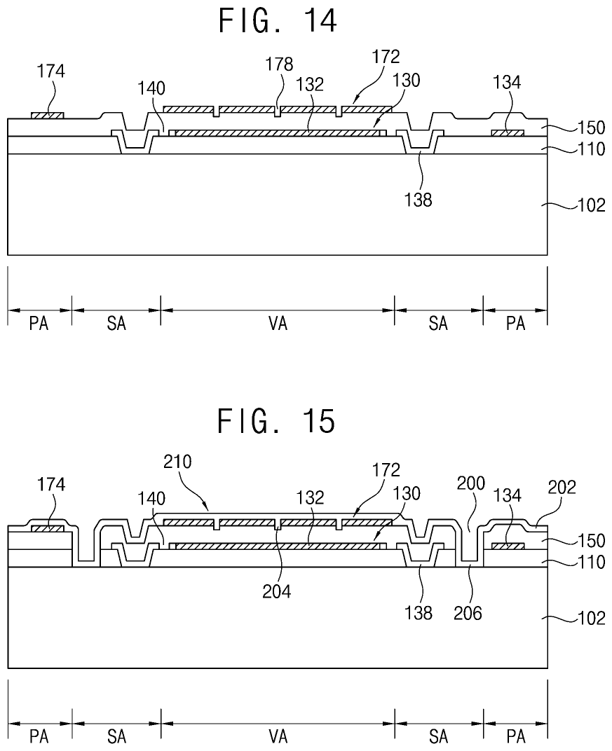

Referring to FIG. 14, the conductive layer 170 may be patterned to form a second electrode layer 172 corresponding to the first electrode layer 132, a second electrode pad 174, and a second connection pattern 176 (refer to FIG. 1) for connecting the second electrode layer 172 and the second electrode pad 174. That is, as shown in FIG. 14, the remaining portions of the conductive layer 170 excluding the second electrode layer 172, the second electrode pad 174, and the second connection pattern 176 may be removed. For example, a photoresist pattern may be formed on the conductive layer 170 to cover regions where the second electrode layer 172, the second electrode pad 174, and the second connection pattern 176 are to be formed, and then, an etching process using the photoresist pattern as an etching mask may be performed until the second insulating layer 150 is exposed.

In accordance with an embodiment of the present disclosure, as shown in FIG. 3, the second electrode layer 172 may include a disk-shaped conductive layer pattern 180 and a reinforcing pattern 182 including a plurality of protrusions 182A protruding outward from the conductive layer pattern 180. In such case, the second electrode layer 172 may have the same size as the first electrode layer 132. That is, the second electrode layer 172 may be formed to have the same thickness and the same area as the first electrode layer 132.

In accordance with another embodiment of the present disclosure, after forming the second silicon layer 160, an ion implantation process may be performed to form a portion of the second silicon layer 160 as a conductive layer pattern 184 (refer to FIG. 4). In addition, the second electrode pad 174 and the second connection pattern 176 may be formed by the ion implantation process. Then, as shown in FIG. 4, the second silicon layer 160 may be patterned to form a reinforcing pattern 186 including a plurality of protrusions 186A. In such case, the conductive layer pattern 184 may be formed of impurity-doped polysilicon, and the reinforcing pattern 186 may be formed of undoped polysilicon. In addition, the conductive layer pattern 184 may have the same size as the first electrode layer 132. That is, the conductive layer pattern 184 may be formed to have the same thickness and the same area as the first electrode layer 132.

In accordance with still another embodiment of the present disclosure, after forming the second silicon layer 160, an ion implantation process may be performed to form a portion of the second silicon layer 160 as a conductive layer pattern 188 (refer to FIG. 5). In addition, the second electrode pad 174 and the second connection pattern 176 may be formed by the ion implantation process. Then, as shown in FIG. 5, the second silicon layer 160 may be patterned to form a reinforcing pattern 190 having a circular ring shape. In particular, the reinforcing pattern 190 may include a plurality of protrusions 190A protruding outward. In such case, the conductive layer pattern 188 may be made of impurity-doped polysilicon, and the reinforcing pattern 190 may be made of undoped polysilicon. Further, the conductive layer pattern 188 may have the same size as the first electrode layer 132. That is, the conductive layer pattern 188 may be formed to have the same thickness and the same area as the first electrode layer 132.

In accordance with still another embodiment of the present disclosure, after forming the second silicon layer 160, an ion implantation process may be performed to form a portion of the second silicon layer 160 as a conductive layer pattern 192 (refer to FIG. 6). In addition, the second electrode pad 174 and the second connection pattern 176 may be formed by the ion implantation process. In particular, as shown in FIG. 6, the conductive layer pattern 192 may be formed to include a plurality of protrusions 192A protruding outward. Subsequently, as shown in FIG. 6, the second silicon layer 160 may be patterned to form a reinforcing pattern 194 having a circular ring shape. In particular, the reinforcing pattern 194 may include a plurality of second protrusions 194A protruding outward. In this case, the conductive layer pattern 192 may be formed of impurity-doped polysilicon, and the reinforcing pattern 194 may be formed of undoped polysilicon. Also, the conductive layer pattern 192 may have the same size as the first electrode layer 132. That is, the conductive layer pattern 192 may be formed to have the same thickness and the same area as the first electrode layer 132.

Referring again to FIG. 14, after forming the second electrode layer 172, a plurality of holes 178 for forming stoppers 204 (refer to FIG. 2) extending toward the first electrode layer 132 may be formed by removing portions of the second electrode layer 172 and the second insulating layer 150. The holes 178 may have a predetermined depth so as to extend through the second electrode layer 172 to a portion of the second insulating layer 150. For example, after forming a photoresist pattern exposing portions where the holes 178 are to be formed on the second electrode layer 172, an anisotropic etching process using the photoresist pattern as an etching mask may be performed for a predetermined time.

Referring to FIGS. 7 and 15, in step S150, a support layer 202 may be formed on the second insulating layer 150 and the second electrode layer 172. Specifically, the second insulating layer 150 and the first insulating layer 110 may be patterned to form a second anchor channel 200 having a circular ring shape surrounding the first anchor portion 138 on the support area (SA). For example, a photoresist pattern exposing portions where the second anchor channel 200 is to be formed may be formed on the second insulating layer 150, and then, an anisotropic etching process using the photoresist pattern as an etching mask may be performed until the upper surface of the substrate 102 is exposed.

After the second anchor channel 200 is formed, a support layer 202 may be conformally formed on the second electrode layer 172 and the second insulating layer 150 to have an approximately uniform thickness. As a result, a back plate 210 including the second electrode layer 172 and the support layer 202 may be formed above the substrate 102. For example, the support layer 202 may be a silicon nitride layer formed by a chemical vapor deposition process. In particular, the support layer 202 may be formed to fill the holes 178, whereby stoppers 204 extending downward from the support layer 202 through the second electrode layer 172 may be formed. In addition, a portion of the support layer 202 formed in the second anchor channel 200 may be used as a second anchor portion 206 for fixing the support layer 202 on the substrate 102.

Referring to FIG. 7, in step S160, bonding pads 222 and 224 electrically connected to the first electrode layer 132 and the second electrode layer 172 may be formed.

Specifically, referring to FIG. 16, a first contact hole (CH1) exposing the first electrode pad 134 may be formed by patterning the support layer 202 and the second insulating layer 150. In addition, a second contact hole (CH2) exposing the second electrode pad 174 may be formed by patterning the support layer 202. For example, after forming a photoresist pattern exposing portions of the support layer 202 corresponding to the first electrode pad 134 and the second electrode pad 174 on the support layer 202, the first contact hole (CH1) and the second contact hole (CH2) may be formed by an anisotropic etching process using the photoresist pattern as an etching mask.

Subsequently, as shown in FIG. 17, a first bonding pad 222 and a second bonding pad 224 may be respectively formed on the first electrode pad 134 and the second electrode pad 174. For example, the first bonding pad 222 and the second bonding pad 224 may be made of a metal such as aluminum, and may be formed by forming an aluminum layer (not shown) on the support layer 202 and then patterning the aluminum layer.

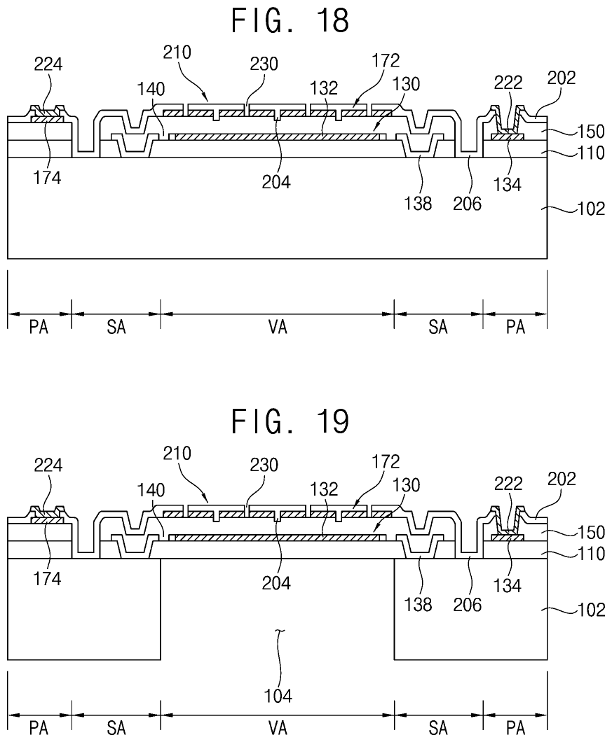

Referring to FIGS. 7 and 18, in step S170, the support layer 202 and the second electrode layer 172 may be patterned to form a plurality of air holes 230. For example, after forming a photoresist pattern exposing portions where the air holes 230 are to be formed on the support layer 202, the air holes 230 may be formed by an anisotropic etching process using the photoresist pattern as an etching mask.

Referring to FIGS. 7 and 19, in step S180, a cavity 104 penetrating through the substrate 102 may be formed. For example, a back grinding process may be performed to reduce the thickness of the substrate 102, and then a cavity 104 penetrating the substrate 102 may be formed. In this case, the cavity 104 may be formed to correspond to the diaphragm 130 and to expose the first insulating layer 110 by an anisotropic etching process.

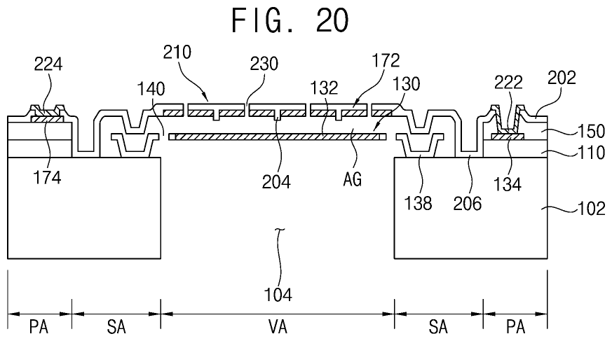

Referring to FIGS. 7 and 20, in step S190, an air gap (AG) may be formed by partially removing the first and second insulating layers 110 and 150. For example, a portion of the first insulating layer 110 and a portion of the second insulating layer 150 formed inside the second anchor portion 206 may be removed by an etching process. In such case, an etching solution or an etching gas may be supplied between the diaphragm 130 and the back plate 210 through the air holes 230 and the ventilation holes 140. As a result, the diaphragm 130 may be exposed downwardly through the cavity 104, and the air gap (AG) may be formed between the diaphragm 130 and the back plate 210.

In accordance with the embodiments of the present disclosure as described above, the reinforcing pattern 182 may increase the structural rigidity of the support layer 202, thereby preventing the support layer 202 from sagging downward and preventing the MEMS microphone 100 from deteriorating in sensitivity. In addition, the thickness of the support layer 202 may be made relatively thin compared to the prior art, and thus the manufacturing cost of the MEMS microphone 100 may be reduced.

Although the example embodiments of the present disclosure have been described with reference to the specific embodiments, they are not limited thereto. Therefore, it will be readily understood by those skilled in the art that various modifications and changes can be made thereto without departing from the spirit and scope of the present disclosure defined by the appended claims.

1. A MEMS microphone comprising:
a substrate having a cavity;
a diaphragm comprising a first electrode layer disposed above the cavity; and
a back plate comprising a second electrode layer disposed above the first electrode layer and a support layer disposed on the second electrode layer,
wherein the second electrode layer comprises a conductive layer pattern, and a reinforcing pattern configured to surround the conductive layer pattern and to increase structural rigidity of the support layer.

2. The MEMS microphone of claim 1, wherein the reinforcing pattern comprises a plurality of protrusions protruding outward from the conductive layer pattern.

3. The MEMS microphone of claim 2, wherein the protrusions are made of a same material as the conductive layer pattern, and the second electrode layer has a same size as the first electrode layer.

4. The MEMS microphone of claim 2, wherein the protrusions are made of a material different from that of the conductive layer pattern, and the conductive layer pattern has a same size as the first electrode layer.

5. The MEMS microphone of claim 4, wherein the conductive layer pattern is made of impurity-doped polysilicon, and the protrusions are made of undoped polysilicon.

6. The MEMS microphone of claim 1, wherein the reinforcing pattern has a ring shape surrounding the conductive layer pattern and comprises a plurality of protrusions protruding outward.

7. The MEMS microphone of claim 1, wherein the conductive layer pattern comprises a plurality of protrusions protruding outward, and the reinforcing pattern has a ring shape surrounding the conductive layer pattern and comprises a plurality of second protrusions protruding outward.

8. The MEMS microphone of claim 7, wherein the conductive layer pattern has a same size as the first electrode layer.

9. The MEMS microphone of claim 1, wherein the diaphragm further comprises a first anchor portion disposed on the substrate to surround the cavity and supporting the first electrode layer.

10. The MEMS microphone of claim 9, wherein the back plate further comprises a second anchor portion disposed on the substrate to surround the first anchor portion and fixing the support layer on the substrate.

11. A method of manufacturing a MEMS microphone, the method comprising:
forming a diaphragm comprising a first electrode layer above a substrate;
forming a back plate comprising a second electrode layer disposed above the first electrode layer and a support layer disposed on the second electrode layer; and
forming a cavity for exposing the diaphragm through the substrate,
wherein the second electrode layer comprises a conductive layer pattern, and a reinforcing pattern configured to surround the conductive layer pattern and to increase structural rigidity of the support layer.

12. The method of claim 11, wherein forming the diaphragm comprises:
forming a first insulating layer on the substrate;
forming a first silicon layer on the first insulating layer; and
performing an ion implantation process to form a portion of the first silicon layer as the first electrode layer.

13. The method of claim 11, wherein forming the back plate comprises:
forming a second insulating layer on the diaphragm;
forming a second silicon layer on the second insulating layer;
performing an ion implantation process to form the second silicon layer as a conductive layer; and
patterning the conductive layer to acquire the conductive layer pattern and the reinforcing pattern,
wherein the reinforcing pattern comprises a plurality of protrusions protruding outward from the conductive layer pattern.

14. The method of claim 13, wherein the second electrode layer has a same size as the first electrode layer.

15. The method of claim 11, wherein forming the back plate comprises:
forming a second insulating layer on the diaphragm;
forming a second silicon layer on the second insulating layer;
performing an ion implantation process to form a portion of the second silicon layer as the conductive layer pattern; and
patterning the second silicon layer to acquire the reinforcing pattern,
wherein the reinforcing pattern comprises a plurality of protrusions protruding outward from the conductive layer pattern.

16. The method of claim 15, wherein the conductive layer pattern has a same size as the first electrode layer.

17. The method of claim 15, wherein the reinforcing pattern has a ring shape surrounding the conductive layer pattern and comprises a plurality of protrusions protruding outward.

18. The method of claim 15, wherein the conductive layer pattern comprises a plurality of protrusions protruding outward, and the reinforcing pattern has a ring shape surrounding the conductive layer pattern and comprises a plurality of second protrusions protruding outward.

19. The method of claim 11, wherein forming the diaphragm comprises:
forming a first insulating layer on the substrate;
patterning the first insulating layer to form a first anchor channel having a circular ring shape surrounding the cavity and exposing a portion of the substrate;
forming a first silicon layer on the first insulating layer and inner surfaces of the first anchor channel;
performing the ion implantation process to form a portion of the first silicon layer formed on the first insulating layer inside the first anchor channel as the first electrode layer; and
patterning the first silicon layer to acquire a first anchor portion for supporting the first electrode layer in the first anchor channel.

20. The method of claim 19, wherein forming the back plate comprises:
forming a second insulating layer on the diaphragm and the first insulating layer;
forming the conductive layer pattern and the reinforcing pattern on the second insulating layer;
patterning the first insulating layer and the second insulating layer to form a second anchor channel having a circular ring shape surrounding the first anchor portion and exposing a portion of the substrate; and
forming a support layer on the conductive layer pattern, the reinforcing pattern, the second insulating layer, and inner surfaces of the second anchor channel,
wherein a portion of the support layer formed on the inner surfaces of the second anchor channel functions as a second anchor portion for fixing the support layer on the substrate.
